(19) United States
(12) Patent Application Publication
(10) Pub. No.: US 2013/0120955 A1
(43) Pub. Date: May 16, 2013

(54) STRUCTURE FOR INSTALLING TUNER

(71) Applicant: SAMSUNG ELECTRO-MECHANICS CO., LTD., Suwon (KR)

(72) Inventor: Sang Roc Lee, Suwon (KR)

(73) Assignee: SAMSUNG ELECTRO-MECHANICS CO., LTD., Suwon (KR)

(21) Appl. No.: 13/673,205

(22) Filed: Nov. 9, 2012

(30) Foreign Application Priority Data
Nov. 11, 2011 (KR) 10-2011-0117291

(51) Int. Cl. H05K 7/02

(52) U.S. Cl. CPC H05K 7/02
USPC 361/814

(57) ABSTRACT

Disclosed herein is a structure for installing a tuner. In the structure for installing a tuner, an edge of a body in which the tuner is installed is formed to have a round shape to bend one side surface of the body and another side surface thereof intersecting with one side surface at a time, such that rigidities of the side surfaces are mutually complemented, thereby making it possible to prevent generation of deformation such as warpage, or the like.

### CROSS REFERENCE TO RELATED APPLICATION

This application claims the benefit of Korean Patent Application No. 10-2011-0117291, filed on Nov. 11, 2011, entitled “The Structure for Set Up a Tuner”, which is hereby incorporated by reference in its entirety into this application.

### BACKGROUND OF THE INVENTION

1. Technical Field

The present invention relates to a structure for installing a tuner.

2. Description of the Related Art

A tuner is embedded in an electronic product such as mobile device, a television, or a video recorder to selectively receive a signal of a desired channel among signals transmitted from a broadcasting station and amplify the received signal to convert the received signal into a signal having an intermediate frequency that is a predetermined frequency required in the electronic product.

Therefore, the electronic product includes a structure embedded therein in order to easily install the tuner. The structure generally indicates a chassis.

The chassis has various forms according to a kind of electronic product. However, commonly, the chassis should have a size smaller than that of the electronic product and should not affect the entire weight and a peripheral device. In addition, the chassis should be easily assembled with an internal substrate of the electronic product.

To this end, the chassis is generally formed in a rectangular shape using a metal plate and has an internal space for installing various terminals including the tuner. This has been disclosed in detail in Patent Document 1, which will be briefly described.

That is, according to Patent Document 1, the chassis is formed in a rectangular shape to have an internal space and includes a hole formed in a side surface thereof in order to caulk and then solder a tuner. Here, the internal space of the chassis is separated by a partition plate to allow a circuit board and terminals to be separately installed therein.

Further, upper and lower covers are coupled to upper and lower portions of the chassis, respectively, to close the internal space, thereby protecting the circuit board and the terminals installed in the internal space and preventing interference between the circuit board and the terminals and a peripheral device.

However, a chassis used as a structure in the prior art including Patent Document 1 has a problem that a side surface thereof, more specifically, a side surface in which a hole for caulking a tuner is formed is deformed when the chassis is assembled with an internal substrate of an electronic product or is transported.

That is, side surfaces of the chassis are generally bent one by one so as to form an internal space. Therefore, a problem in durability is generated due to weak rigidity, such that the deformation such as warpage, or the like, of the side surface may be generated when the chassis is assembled with the internal substrate of the electronic product or is transported.

### PRIOR ART DOCUMENT

### Patent Document

(Patent Document 1) KR2007-0103110 A

### SUMMARY OF THE INVENTION

The present invention has been made in an effort to provide a structure for installing a tuner capable of preventing deformation generated at the time of assembling or transporting.

According to a preferred embodiment of the present invention, there is provided a structure for installing a tuner, the structure including: a body having a tuner installed therein, wherein the body includes: a first end portion formed so that an internal space is formed in the body; a second end portion formed at the body so as to intersect with the first end portion; and a connection part formed integrally with the first and second end portions therebetween so as to have a round shape.

According to another preferred embodiment of the present invention, there is provided a structure for installing a tuner, the structure including: a body having a tuner installed therein; and an extension part formed at one side of the body, wherein the extension includes a first end portion formed so that an internal space is formed in the body and the extension part, and the body includes a second end portion formed so as to intersect with the first end portion, the first and second end portions having a connection part formed integrally therewith therebetween and a round shape.

The body may include opening parts formed therein in order to expose the internal space to the outside.

The body and the extension part may include opening parts formed therein in order to expose the internal space to the outside.

The first or second end portion may be provided with holes for caulking the tuner.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a structure for installing a tuner according to a first preferred embodiment of the present invention;

FIG. 2 is a perspective view showing a structure for installing a tuner according to a second preferred embodiment of the present invention; and

FIG. 3 is an exploded perspective view showing a cover and a chassis that are the structure for installing a tuner of FIG. 2

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

The present invention relates to a structure for easily embedding a tuner in an electronic product including a mobile device, a television, or a video recorder, or the like, wherein the structure includes a body 10 having the tuner installed therein.

The body 10 may have various sizes and shapes according to a kind of electronic product in which the tuner is embedded. Therefore, the case in which the tuner is installed in the mobile device will be described in the present embodiment.

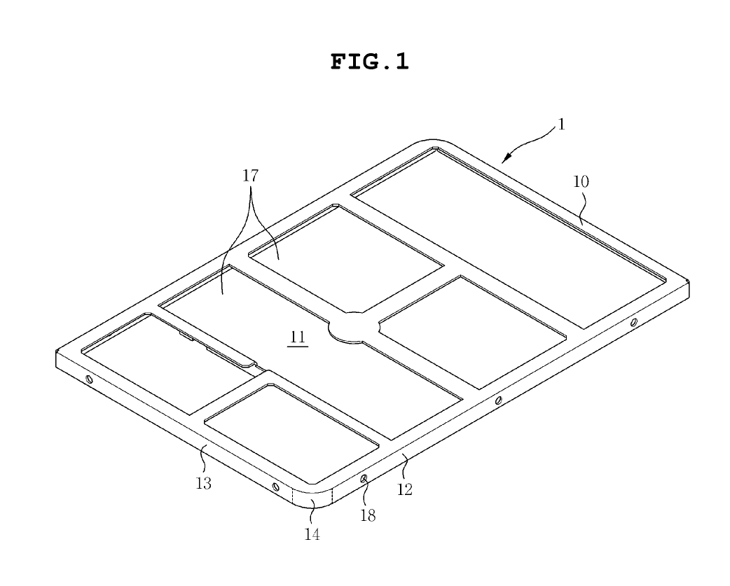

As shown in FIG. 1, in a first preferred embodiment of the present invention, the body 10 is formed in a rectangular shape and is generally made of a metal material. More specifically, the body 10 is formed in the rectangular shape using a metal plate having a thickness of about 1 mm.

The body 10 formed as described above includes an internal space 11 and receives a circuit board and terminals in the internal space 11. Therefore, the body 10 has a rectangular parallelepiped shape in order to form the internal space 11.

That is, each of the end portions of the body 10 is bent in one direction (a downward direction in FIG. 1) to form a kind of side surface, such that the body 10 has the rectangular parallelepiped shape. Therefore, the body 10 receives the circuit board and the terminals in the internal space 11 formed therein.

The side surfaces are formed as follows. First, a first end portion 12 is formed at one side of the body 10. Then, a second end portion 13 is formed at the other side of the body 10 so as to intersect with the first end portion 12.

In the present description, terms “first”, “second”, and so on, are used to distinguish one element from another element, and the elements are not limited by the above terms.

Then, a connection part 14 is formed integrally with the first and second end portions 12 and 13 therebetween so as to have a round shape. That is, the connection part 14 is formed at a portion generally called an edge of the body 10.

After the first and second end portions 12 and 13 and the connection part 14 are formed integrally with each other at the body 10 as described above, the first and second end portions 12 and 13 and the connection part 14 are bent in the same direction at a time to form the side surface of the body 10. The bending is performed using a press, or the like.

That is, the first and second end portions 12 and 13 are bent at a time through the connection part 14 by the press, or the like, to form the side surfaces of the body 10, such that rigidity of the side surfaces are improved as compared to the case according to the prior art in which side surfaces are formed one by one through bending, thereby making it possible to prevent deformation such as warpage, or the like.

Here, dotted lines between the first end portion 12 and the connection part 14 and between the second end portion 13 and the connection part 14 is to be interpreted as a meaning of a boundary line arbitrarily formed so as to easily distinguish the connection part 14 from the first and second end portions 12 and 13 and does not mean a state in which the connection part 14 is separated from the first and second end portions 12 and 13.

The structure according to the first preferred embodiment of the present invention having the side surfaces formed at the body 10 is generally called a cover in the art and has a closed internal space 11.

Unlike this, opening parts 17 may be formed in the body 10 in order to expose the internal space 11 to the outside. The structure according to the first preferred embodiment of the present invention having the opening parts 17 formed in the body 10 is generally called a chassis in the art. FIG. 1 shows the chassis 1.

In addition, the body 10 used as the cover 2 and the chassis 1 includes caulking holes 18 formed therein so as to caulk the tuner at inner and outer portions thereof. More specifically, a plurality of caulking holes 18 are formed at the first and second end portions 12 and 13 so as to easily caulk the tuner.

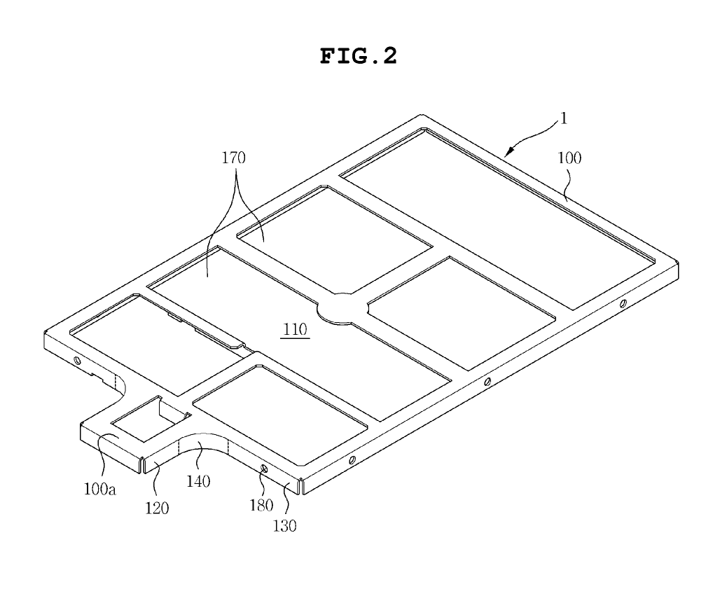

Meanwhile, in the second preferred embodiment of the present invention, a body 100 has a non-rectangular shape, as shown in FIG. 2. That is, an extension part 100a protrudes at one side of the body 100 and is extended to the outside to form the body 100 having the non-rectangular shape.

In this case, as a material of the body 100, a metal material is generally used. More specifically a metal plate having a thickness of about 1 mm is used.

The body 100 and the extension part 100a formed as described above are provided with an internal space 110 and receive a circuit board and terminals in the internal space 110. Therefore, the body 100 has the entirely rectangular parallelepiped shape in order to form the internal space 110.

That is, each of the end portions of the body 10a and the extension part 100a is bent in one direction (a downward direction in FIG. 2) to form a kind of side surface, such that the body 100 has the entirely rectangular parallelepiped shape. Therefore, the body 100 receives the circuit board and the terminals in the internal space 110.

The side surfaces are formed as follows. First, a first end portion 120 is formed at one side of the extension part 100a. Then, a second end portion 130 is formed at one side of the body 100 so as to intersect with the first end portion 120.

Then, a connection part 140 is formed integrally with the first and second end portions 120 and 130 therebetween so as to have a round shape. That is, the connection part 140 is formed at a portion, which is generally called a groove or a valley, between the extension part 100a and the body 100.

After the first and second end portions 120 and 130 and the connection part 140 are formed integrally with each other at the body 100 as described above, the first and second end portions 120 and 130 and the connection part 140 are bent in the same direction at a time to form the side surface of the body 100. The bending is performed using a press, or the like.

That is, the first and second end portions 120 and 130 are bent at a time through the connection part 140 by the press, or the like, to form the side surfaces of the body 100 and the extension part 100a, such that rigidities of the sides surface are improved as compared to the case according to the prior art in which side surfaces are formed one by one through bending, thereby making it possible to prevent deformation such as warpage, or the like. Particularly, it is possible to easily prevent the extension part 100a protruding from the body 100 to have relatively weak durability from being deformed during an assembling process and a transporting process.

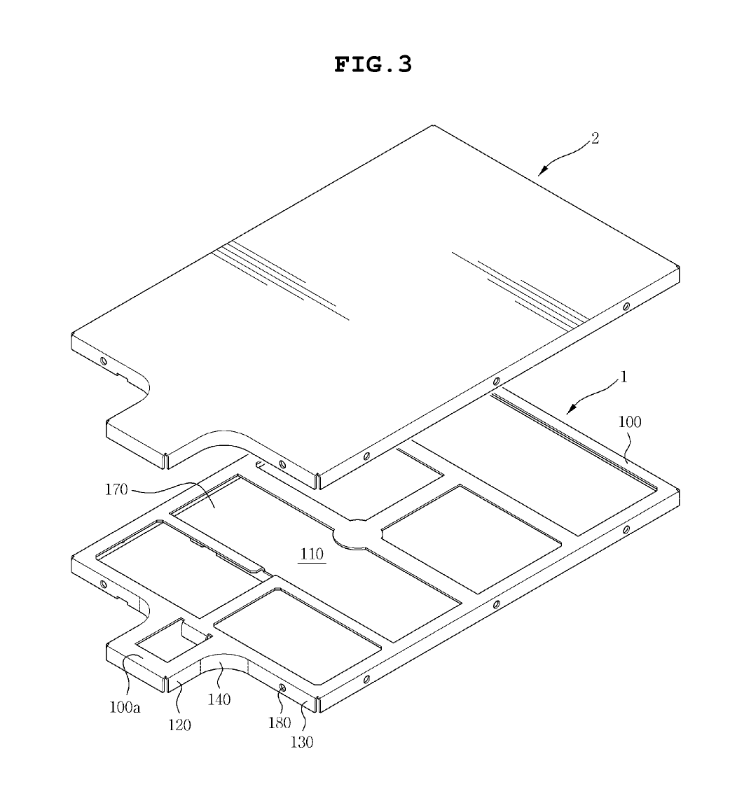

The structure according to the second preferred embodiment of the present invention having the side surfaces formed at the body 100 and the extension part 100a is generally called a cover 2 in the art and has a closed internal space 110. A structure positioned at an upper portion in FIG. 3 corresponds to the cover 2.

Unlike this, opening parts 170 may be formed in the body 100 and the extension part 100a in order to expose the internal space 110 to the outside. The structure according to the second preferred embodiment of the present invention having the opening parts 170 is generally called a chassis in the art. A structure positioned at a lower portion in FIG. 3 corresponds to the chassis 1.

In addition, the body 100 used as the cover 2 and the chassis 1 includes caulking holes 180 formed therein so as to caulk the tuner at inner and outer portions thereof. More specifically, a plurality of caulking holes 180 are formed at the first and second end portions 120 and 130 so as to easily caulk the tuner.

As set forth above, according to the preferred embodiments of the present invention, the first and second end portions are bent at a time through the connection part formed integrally therewith and having the round shape, such that rigidities of the first and second end portions and the connection part are mutually complemented, thereby making it possible to preventing the deformation such as the warpage, or the like, in a process in which the structure for installing a tuner is assembled with an internal substrate of an electronic product or is transported.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A structure for installing a tuner, the structure comprising:
a body having a tuner installed therein,
wherein the body includes:
a first end portion formed so that an internal space is formed in the body;
a second end portion formed at the body so as to intersect with the first end portion; and
a connection part formed integrally with the first and second end portions therebetween so as to have a round shape.

2. A structure for installing a tuner, the structure comprising:
a body having a tuner installed therein; and
an extension part formed at one side of the body,
wherein the extension includes a first end portion formed so that an internal space is formed in the body and the extension part, and
the body includes a second end portion formed so as to intersect with the first end portion,
the first and second end portions having a connection part formed integrally therewith therebetween and a round shape.

3. The structure as set forth in claim 1, wherein the body includes opening parts formed therein in order to expose the internal space to the outside.

4. The structure as set forth in claim 3, wherein the first or second end portion is provided with holes for caulking the tuner.

5. The structure as set forth in claim 2, wherein the body and the extension part include opening parts formed therein in order to expose the internal space to the outside.

6. The structure as set forth in claim 5, wherein the first or second end portion is provided with holes for caulking the tuner.
